(19) United States
(12) Patent Application Publication
(10) Pub. No.: US 2017/0159179 A1
(43) Pub. Date: Jun. 8, 2017

(54) Nozzle Head, Apparatus and Method for Subjecting Surface of Substrate to Successive Surface Reactions

(71) Applicant: Beneq Oy, Espoo (FI)

(72) Inventors: Pekka Soininen, Espoo (FI); Mikko Soderlund, Espoo (FI); Janne Peltoniemi, Espoo (FI)

(21) Appl. No.: 15/323,779

(22) PCT Filed: Jul. 3, 2015
(86) PCT No.: PCT/FI2015/050483

§ 371 Date: Jan. 4, 2017

(30) Foreign Application Priority Data
Jul. 7, 2014 (FI) 20145655

(51) Int. Cl. C23C 16/455

(52) U.S. Cl. CPC C23C 16/45544; C23C 16/45574; C23C 16/45551

(57) ABSTRACT

The invention relates to a nozzle head, an apparatus and method for subjecting a surface of a substrate to successive surface reactions of at least a first precursor (A) and a second precursor (B). The nozzle head having an output face comprises at least one precursor nozzle for supplying precursor (A, B) to the surface of the substrate and at least one discharge channel for discharging precursor (A, B) from the surface of the substrate. The output face comprises in the following order: a discharge channel, at least one at least one precursor nozzle arranged to supply the first precursor (A) and the second precursor (B) and a discharge channel.

### FIELD OF THE INVENTION

The present invention relates to a nozzle head according to the preamble of claim 1 and more particularly to a nozzle head for subjecting a surface of a substrate to successive surface reactions of at least a first precursor and a second precursor, the nozzle head having an output face comprising one or more precursor nozzles arranged to supply the first precursor and the second precursor to the surface of the substrate and at least two discharge channels for discharging precursor from the surface of the substrate.

The present invention further relates to an apparatus according to the preamble of claim 9 and more particularly to an apparatus for subjecting a surface of a substrate to successive surface reactions of at least a first precursor and a second precursor, the apparatus comprising a nozzle head for supplying precursors to the surface of the substrate, the nozzle head comprises an output face having one or more precursor nozzles arranged to supply the first precursor and the second precursor to the surface of the substrate and at least one discharge channel for discharging precursors from the surface of the substrate and a precursor supply system comprising a first precursor source for the first precursor, a second precursor source for the second precursor and precursor conduits for conveying precursor from the first and second precursor sources to the at least one precursor nozzle of the nozzle head.

The present invention also relates to a method according to the preamble of claim 25 and more particularly to a method for coating a substrate, the method comprises arranging a nozzle head over the surface of the substrate, the nozzle head having an output face comprising at least one precursor nozzle for supplying precursor to the surface of the substrate and at least one discharge channel for discharging precursor from the surface of the substrate and subjecting the surface of the substrate to successive surface reactions of at least a first precursor and a second precursor.

### BACKGROUND OF THE INVENTION

Atomic layer deposition (ALD) is conventionally carried out in a reaction chamber under vacuum conditions. One or more substrates are first loaded into the reaction chamber and then vacuum is provided or sucked into the reaction chamber and the reaction space inside the reaction chamber is heated to process temperature. The atomic layer deposition is then carried out by supplying at least first and second gaseous precursors into the reaction chamber alternatingly and repeatedly for providing a coating layer with desired thickness on the surface of the substrate. A full ALD cycle, in which the first and second precursor are supplied into the reaction chamber comprises: supplying a pulse of first precursor into the reaction chamber, purging the first precursor from the reaction chamber, supplying a pulse of second precursor into the reaction chamber and purging the second precursor from the reaction chamber. Purging precursors may comprise discharging the precursor material from the reaction chamber, supplying purge gas, such as nitrogen, into the reaction chamber and discharging the purge gas. When desired number of ALD cycles and thus a desired coating layer thickness is reached, the vacuum in the reaction chamber is released and the substrates are unloaded from the reaction chamber. Then the same process is repeated for the next substrates.

One of the disadvantages associated with the above described conventional method of carrying out an ALD method and a related apparatus is that process is very slow for industrial purposes, especially when large substrates large substrates are processed in large reaction chambers. To increase the time-averaged throughput, typically a number of substrates are processed in one large batch. In such a batch process, time for carrying out one ALD cycle lasts usually approximately 10 to 40 seconds, depending on the process volume, reaction chamber volume and other conditions. In addition to the ALD cycle time, providing vacuum and releasing it as well heating the reaction space takes significant amount of time. Thus providing coating layers on substrates is inefficient for industrial manufacturing processes as the throughput of the coating process remains at low level. Another disadvantage of the conventions batch ALD process relates to the basic characteristic of the ALD, meaning that the whole substrate is coated and processed in the reaction space due to the extremely high conformality of ALD. However, often it is not desirable to coat all the surface of the substrate and thus different kinds of masks have to be used on the surface of the substrates in order to prevent coating from growing on certain parts of the substrates. Masking is very difficult as the precursor gases tend to diffuse between the mask and the surface of the substrate and thus quality is compromised. Another alternative is to remove coating, for example with etching, after the ALD coating process. Masking and etching are also difficult and time consuming operations and thus further slow the process down and make the ALD less suitable or industrial purposes. The advantage of the conventional batch ALD process is that the process may be controlled in high detail and the produced coating is of very high quality. The speed of the ALD cycle in the batch processing is determined by the frequency of the alternating precursor pulses, meaning the time it takes to supply and purge the precursor pulses. However, the pulse frequency is limited by the volume of the reaction chamber as the amount of supplied precursors must be enough to subject the whole surface of the surface to precursors while the precursors react also with the walls of the reaction chamber. It also takes time to purge the whole reaction chamber which further limits the ALD cycle time.

In the prior art the above disadvantages are tried to be overcome by using movable nozzle head which comprise at least one first precursor nozzle for supplying first precursor on the surface of the substrate, at least one second precursor nozzle for supplying second precursor on the surface of the substrate and at least one discharge channel for discharging the precursors from the surface of the substrate. The nozzle head comprises on output face to which the precursor nozzles and the discharge channel are provided. The nozzle head is arranged over a surface of the substrate to be coated and moved in reciprocating or similar manner over the surface in relation to the substrate. The precursors are continuously and uninterruptedly supplied from the precursor nozzles and also discharge to discharge channels. The relative movement and continuous supply of the precursors subjects the surface of the substrate alternatively and repeatedly to the first and second precursors and grows coating layers on the surface of the substrate. The advantage of using a nozzle head is that the successive precursor supply and purge steps may be omitted as the supply of the precursors and the discharge of the precursors is carried out continuously. Accordingly, the ALD cycle time is dependent on the relative moving speed of the substrate and the nozzle head and it may be possible to decrease the ALD cycle time in relation to conventional batch process. Furthermore, there is no need for batch processing and thus generating and releasing the vacuum may be omitted. Using a nozzle head also enables coating only one surface of the substrate or a part of a surface over which the nozzle is arranged.

One of the disadvantages of using a nozzle head as mentioned above is that to keep the two precursors apart from each other in gas phase, the nozzle head must be kept in close proximity to the substrate. When large substrates are coated the size of the nozzle head becomes also large and controlling tiny mechanical tolerances over such large areas becomes increasingly difficult, leading to compromised coating quality. Gas phase reactions of the precursors lead to generation of particles, which not only reduce the coating quality, but also leads to increased maintenance requirement. Furthermore, the relative movement becomes difficult carry out and the forces generated due to the repeatedly accelerating and decelerating movements become prohibitive. This means that nozzle head cannot be used reasonably when large substrates are processed and coated. The nozzle head also has to move entirely over the surface of the substrate for achieving the desired thickness of the coating. This causes soiling of the apparatus and excess use of precursors as precursors are supplied outside the edges of the substrate.

### BRIEF DESCRIPTION OF THE INVENTION

An object of the present invention to provide a nozzle head, an apparatus and a method so as to overcome or at least alleviate the above mentioned prior art disadvantages. The objects of the present invention are achieved by a nozzle head according to the characterizing portion of claim 1 in which the output face comprises in the following order: a discharge channel, at least one precursor nozzle arranged to supply the first precursor and the second precursor and a discharge channel. The objects of the present invention are also achieved with an apparatus according to the characterizing portion of claim 9 in which the output face of the nozzle head comprises in the following order: a discharge channel, at least one precursor nozzle and a discharge channel and precursor conduits of the precursor supply system are arranged to convey first precursor from the first precursor source and second precursor from the second precursor source to the at least one precursor nozzle provided to the nozzle head for supplying the first and second precursor to the surface of the substrate between two successive discharge channels at the output face for forming one or more reaction zones. The objects of the present invention are also achieved with a method according to the characterizing portion of claim 25 in which the method further comprises supplying the first and second precursors from the at least one precursor nozzle alternatingly to the surface of the substrate via the output face comprising in the following order: a discharge channel, at least one precursor nozzle arranged to supply the first precursor and the second precursor and a discharge channel.

The present invention is based on providing a nozzle head which is arranged over a surface of a substrate for subjecting the surface of the substrate to alternating surface reaction of at least a first and second precursor according to the principles of ALD. The nozzle head comprises an output face having one or more precursor nozzles and one or more discharge channels, or two or more precursor nozzles and two or more discharge channels. According to the present invention the output face comprises in the following order: a discharge channel, one or more precursor nozzles and a discharge channel for subjecting the surface of the substrate to alternating surface reactions of the first and second precursor in a reaction zone between the discharge channels. The output face may comprise at least one first precursor nozzle for supplying the first precursor and at least one second precursor nozzle for supplying the second precursor provided between the two successive discharge channels. Alternatively the output face may comprise at least one a common precursor nozzle for the at least first and second precursor such that they may be supplied alternatingly on the surface of the substrate via the same common precursor nozzle.

The present invention further provides an apparatus comprising a nozzle head and precursor supply system. The precursor supply system comprises at least a first and second precursor source for the first and second precursors and precursor conduits for conveying the precursors from the precursor sources to the precursor nozzles of the nozzle head. In the present invention the output face of the nozzle head comprises at least one precursor nozzle arranged between two discharge channels and the precursor conduits of the precursor supply system are arranged to convey first precursor from the first precursor source and second precursor from the second precursor source to the at least one precursor nozzle for supplying the first and second precursor to the surface of the substrate between two successive discharge channels at the output face for forming one or more reaction zones. The precursor conduits of the precursor supply system may be arranged to convey first precursor from the first precursor source and second precursor from the second precursor source to at least one common precursor nozzle provided to the nozzle head for supplying first and second precursor to the surface of the substrate via same common precursor nozzle. Alternatively the precursor conduits of the precursor supply system are arranged to convey first precursor from the first precursor source to the first precursor nozzle and second precursor from the second precursor source to the second precursor nozzle for supplying first and second precursor to the surface of the substrate between successive discharge channels.

The present invention further relates to a method for processing a surface of a substrate according to the principles of ALD by using the nozzle head and apparatus according to the present invention. The method comprises arranging a nozzle head over the surface of the substrate and subjecting the surface of the substrate to successive surface reactions of at least a first precursor and a second precursor. In the present invention the method further comprises supplying the first and second precursors from the at least one precursor nozzle alternatingly to the surface of the substrate via the output face comprising the at least one precursor nozzle arranged between two successive discharge channels. The method may further comprise supplying alternatingly in succession the first precursor from a first precursor nozzle via the output face to the surface of the substrate and the second precursor from a second precursor nozzle via the output face to the surface of the substrate for growing coating layers on the surface of the substrate. Alternatively the present invention may further comprise supplying alternatingly in succession the first precursor and the second precursor from a common precursor nozzle via the output face to the surface of the substrate for growing coating layers on the surface of the substrate.

Accordingly at least first and second precursors are supplied alternatingly in a pulsed manner as in a conventional batch type ALD process and preferably discharged continuously via the discharge channel. A reaction zone is formed between the at least one precursor nozzle and the adjacent discharge channel, or between two successive discharge channels. In the reaction zone the surface of the substrate is subjected to both the first and second precursor as the first and second precursor are supplied in pulsed manner alternatingly and successively from the at least one precursor nozzle and discharged via the discharge channel. Therefore, coating layers are grown on the surface of the substrate located in reaction zone.

An advantage of the nozzle head, apparatus and method of the present invention is that it allows very fast and selected-area coating of large area substrates. The precursor nozzle and the discharge channel can be arranged so as to minimize the cycle time over the reaction zone, formed between the precursor nozzle and the discharge channel. By limiting a given reaction zone area, the both the precursor dose and the related purge times can be minimized in order to reduce the cycle time across the reaction zone. Multiple of such reaction zones can then be added in a modular way onto a nozzle head, allowing scaling of the nozzle head to very large surface areas without compromise to the cycle time and throughput. Furthermore, the present invention enables processing the substrate without loading the substrates into a reaction chamber, providing a vacuum into the reaction chamber and purging the whole reaction chamber. When the precursors are alternatingly supplied on the surface of the substrate via a common precursor nozzle there is no need to move the substrate and the nozzle head in relation to each other. The discharge of the precursors may be at the same time carried out continuously, and therefore the separate purge time may be omitted. Accordingly the ALD cycle time is limited only by frequency and duration of the alternating precursor pulses supplied via the common precursor nozzle. The ALD cycle time is short because the purge may be omitted and there is no reaction chamber which is successively filled and exhausted from precursors and purge gas. The purge time is also short as the distance to be purged is short. Therefore, purge gas passes through the reaction chamber quickly as gas a front and thus significant turbulence is not generated in the gas front. This same applies to precursor supply.

The approach of the present invention also improves precursor material utilization efficiency, especially in comparison to batch processing, where significant overdosing of precursor is required to achieve surface saturation across the full batch surface area. Furthermore, several ALD process chemistries exhibit high non-uniformity over large area deposition. One such example if TiO₂ film deposition using TiCl₃ and H₂O precursors, where process byproduct HCl can cause high film non-uniformity. Advantage of the nozzle head is that the reaction zone length can be optimized for specific precursor chemistries and achieve high uniformity over very large substrate areas. Furthermore, the present invention enables processing only limited parts of the substrates without need for attaching masks on the surface of the substrate or removing coatings after the ALD process. This may be achieved by using the apparatus and nozzle head according to the present invention such that the nozzle is arranged on only the limited part of the surface of the substrate or that the apparatus and the nozzle is arranged to expose only the limited part of the surface of the substrate to both the first and second precursor materials. As the coating is limited to the substrate face, the nozzle head, and the precursor discharge conduits, there are less parts requiring regular maintenance, and the design of these parts can be made so as to minimize system downtime during the part change. As the precursor materials are alternatingly pulsed with the precursor supply system, high quality coatings may be achieved as there is no significant risk for unwanted reactions of the precursors. Accordingly the present invention enables very short ALD cycle times and coating growth rates for substrates, also for large substrates, without complex apparatuses and compromised coating quality.

### BRIEF DESCRIPTION OF THE DRAWINGS

In the following the invention will be described in greater detail by means of preferred embodiments with reference to the attached [accompanying] drawings, in which

FIG. 1 shows schematically one embodiment of an apparatus according to the present invention with first and second precursor nozzles;

FIG. 2 shows schematically one embodiment of a nozzle head according to the present invention with first and second precursor nozzles;

FIG. 3 shows schematically another embodiment of an apparatus according to the present invention with first and second precursor nozzles;

FIG. 4 shows schematically another embodiment of a nozzle head according to the present invention with first and second precursor nozzles;

FIG. 5 shows schematically one embodiment of an apparatus according to the present invention with a common precursor nozzle;

FIG. 6 shows schematically one embodiment of a nozzle head according to the present invention with a common precursor nozzle;

FIGS. 7 and 8 show schematically other embodiments of a nozzle head according to the present invention with a common precursor nozzle;

FIG. 9 shows schematically the embodiment of FIG. 1 with a mask;

FIG. 10 shows schematically one embodiment of a mask;

FIG. 11 shows schematically another embodiment of an apparatus according to the present invention with a common precursor nozzle;

FIG. 12 shows schematically yet another embodiment of an apparatus according to the present invention with a common precursor nozzle;

FIGS. 13, 14 and 15 show schematically one embodiment of operating an apparatus according to the present invention.

### DETAILED DESCRIPTION OF THE INVENTION

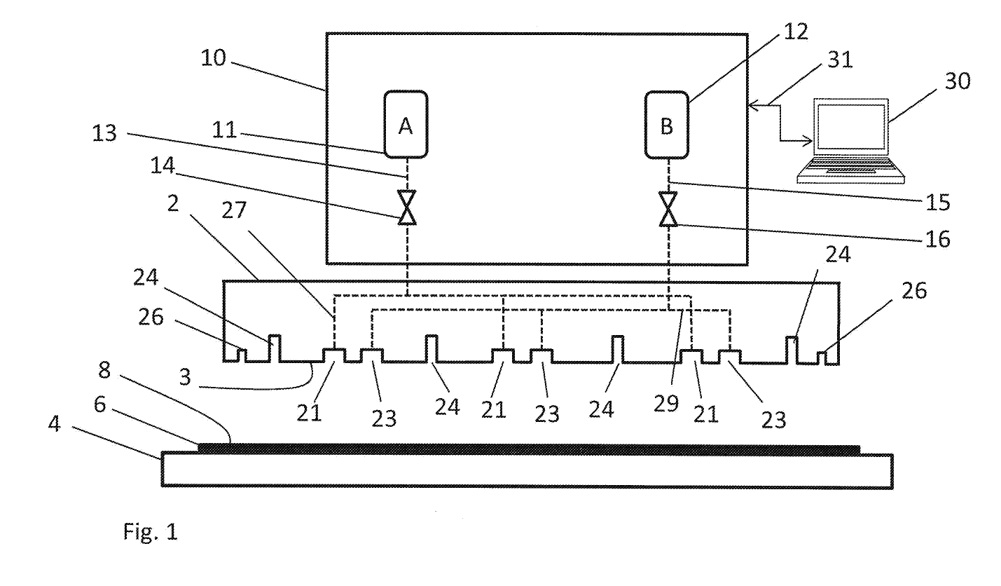

FIG. 1 is one embodiment of an apparatus according to the present invention for subjecting a surface 8 of a substrate 6 to successive surface reactions of at least a first precursor A and a second precursor B. The apparatus comprises nozzle head 2, or precursor supply element, precursor supply system 10 and a control unit 30. The apparatus may further comprise a substrate support 4 for supporting the substrate 6 during processing.

The nozzle head 2 for supplying precursors A, B to the surface 8 of the substrate 6 comprises an output face 3 having at least one first precursor nozzle 21 for supplying first precursor A and at least one second precursor nozzle 23 for supplying second precursor B to the surface 8 of the substrate 6 and at least two discharge channels 24 for discharging precursor A, B from the surface 8 of the substrate 6, as shown in FIG. 1. The output face 3 may further comprise a circumferential edge discharge channel 26 surrounding the precursor channels 22 and the discharge channels 24. Alternatively or additionally the output face 3 also comprise a circumferential edge shield gas channel (not shown) surrounding the precursor channels 22 and the discharge channels 24 for supplying inert shield gas, such as nitrogen. The nozzle head 2 is schematically shown to be arranged such that the output face 3 of the nozzle head is over surface 8 of the substrate 6 during processing. The distance between the output face 3 and the surface 8 of the substrate 6 is arranged to be as small as possible such that precursors are not leaked to the surrounding atmosphere and the efficiency of the precursor use is at high level. The nozzle head 2 may be any mechanical structure and preferably manufactured from metal. The nozzle head 2 may be a solid element into which the precursor nozzles 22, discharge channels 24 and related conduits are machined, or alternatively it may be multi-part element comprising a body and separate conduits, precursor nozzles 22 and discharge channels 24 arranged to the body.

The apparatus comprises a precursor supply system 10 comprising at least a first precursor source 11 for the first precursor A, and a second precursor source 12 for the second precursor B. The precursor supply system 10 comprises also precursor conduits 13, 15, 27, 29 for conveying precursor A, B from the precursor source 11, 12 to the precursor nozzles 21, 23 of the nozzle head 2, as shown in FIG. 1. The precursor supply system 10 may also comprise more than two precursor sources for more than two different precursor materials, respectively, and associated precursor conduits. Furthermore, there may also be a purge gas source and respective purge gas conduits. The apparatus further comprises a control system 30, 32 arranged to control the supply of the at least first and second precursor A, B to the precursor nozzles 21, 23. In one embodiment the control system 30 may comprise a computer or a microprocessor connected via data transfer connection 31 to the precursor supply system.

According to the present invention the precursor conduits 13, 15, 27, 29 of the precursor supply system 10 are arranged to convey first precursor A from the first precursor source 11 to the first precursor nozzles 21 and second precursor B from the second precursor source 12 to the second precursor nozzles 23 for supplying first and second precursor A, B to the surface 8 of the substrate 6 via the output face 3. Also possible purge gas may be supplied via the first and second precursor nozzles 21, 23.

FIG. 1 shows one embodiment in which the precursor supply system 10 comprises a first sub-conduit 13 extending from the first precursor source 11 and a second sub-conduit 15 extending from the second precursor source 12 for conveying the first and second precursor from the precursor sources 11, 12 to the first and second precursor nozzles 21, 23, respectively. The first and second sub-conduit 13, 15 are provided with first and second precursor valves 14, 16, respectively, for controlling the flow of the first and second precursor A, B from the first and second precursor sources 11, 12. The first and second sub-conduits 13, 15 may further be branched to two or more branch sub-conduits 27, 29 extending to the first and second precursor nozzles 21, 23, as shown in FIG. 1. The first and second precursors A, B are conveyed via separate sub-conduits 13, 27, 15, 29 from the precursor sources 11, 12 to the first and second precursor nozzles 21, 23.

The precursor supply system 10 may further comprise discharge pump for generating suction to discharge channels 24, discharge conduits (not shown) and discharge tank for discharging the precursors from the surface 8 of the substrate 6. The precursors may be supplied continuously or in pulsed manner. There are several different pulsing techniques and the present invention is not limited to any specific pulsing technique.

The nozzle head 2 according to the present invention for subjecting the surface 8 of the substrate 6 to successive surface reactions of at least the first precursor A and the second precursor B, as shown in FIG. 1, has an output face 3 comprising at least one first and second precursor nozzle 21, 23 via which precursor A, B is supplied to the surface 8 of the substrate 6 and at least two discharge channels 24, 26 for discharging precursors A, B from the surface 8 of the substrate 6. According to the above mentioned the output face 3 comprises in the following order: a discharge channel 24, at least one first and second precursor nozzle 21, 23 arranged to supply the first precursor A and the second precursor B and a discharge channel 24, repeated one or more times. Accordingly, there may be one or more first and second precursor nozzles 21, 23 arranged between two successive discharge channels 24, in any order. A reaction zone in which the surface 8 of the substrate 6 is subjected to alternating surface reactions of the first and second precursors A, B is thus formed between the successive two discharge channels 24 between which the precursor nozzles 21, 23 are arranged.

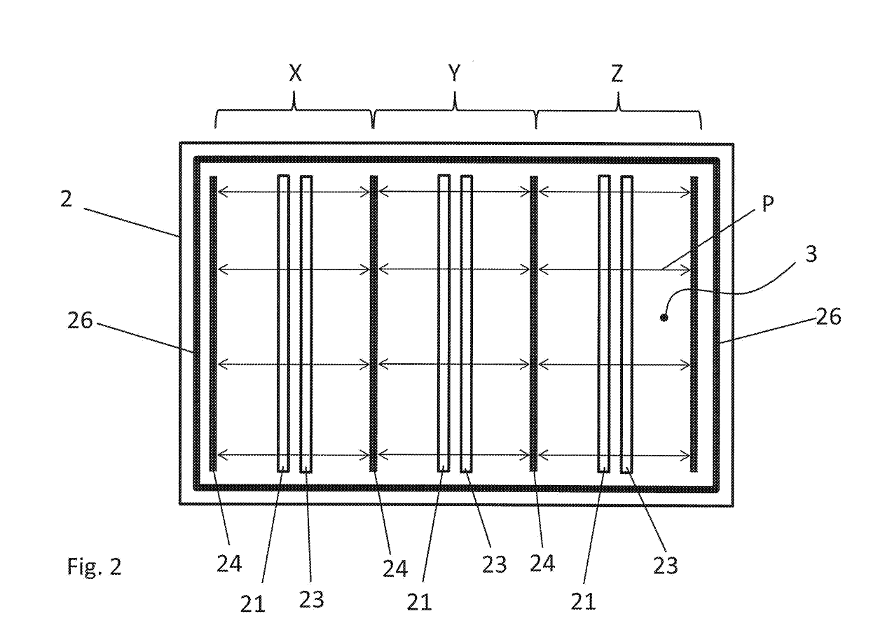

FIG. 2 shows one embodiment of the output face 3 of the nozzle head 2. The output face 3 is arranged over or on the surface 8 of the substrate 6 for supplying the precursors A, B on the surface 8 via the first and second precursor nozzles 21, 23. In this embodiment the first and second precursor nozzles 22 are longitudinal channels open to the output face 3 of the nozzle head 2. The first and second precursor nozzles 21, 23 are arranged adjacent to each other. Similarly the discharge channels 24 are longitudinal channels open to the output face 3 of the nozzle head 2. In FIG. 2 the longitudinal first and second precursor nozzles 21, 23 and discharge channels 24 are linear and straight, but they may also be curved or be of some other shape. The first and second precursor nozzles 21, 23 may comprise one or more supply openings (not shown) arranged along the length of the first and second precursor nozzles 21, 23 from which the precursors A, B flow from precursor conduits 27, 29. Alternatively, the first and second precursor nozzles 21, 23 may comprise a longitudinal supply slit or gap extending along the length of the first and second precursor nozzles 21, 23 from which the precursors A, B enter the first and second precursor nozzles 21, 23 from the precursor conduits 27, 29. The discharge channel 24 may also be provided in the similar manner with one or more discharge openings or one or more slits or gaps along the length of the discharge channel 24. It should be noted that while in the embodiment of FIG. 2 there are provided three first and second precursor nozzles 21, 23 to the output face 3, there may also be only one or two first and second precursor nozzles 21, 23 or alternatively more than three.

As shown in FIG. 2 the first and second precursor nozzles 21, 23 are longitudinal channels open to the output face 3 and the discharge channels 24 are longitudinal channels open to the output face 3. The first and second precursor nozzles 21, 23 and the discharge channels 24 extend substantially parallel in the output face 3 for providing a reaction zones X, Y, Z between the adjacent the precursor nozzles 21, 23 and the discharge channels 24, and between successive discharge channels 24. In principle the output face 3 may comprise one or two or more longitudinal first and second precursor nozzles 21, 23 arranged to supply both the first and second precursor A, B and two or three or more longitudinal discharge channels 24 arranged to discharge precursors A, B. The first and second precursor nozzles 21, 23 and the discharge channels 24 may be arranged alternatingly in substantially parallel to some other pattern to the output face 3 for providing reaction zones X, Y, Z between the successive discharge channels 24.

The precursors A, B are supplied from the first and second precursor nozzles 21, 23 and they flow towards the adjacent discharge channels 24 as shown in FIG. 2 with arrows P. Then the reaction zones X, Y and Z are formed between the first and second precursor nozzle 21, 23 and the adjacent discharge channels 24, or between the two successive discharge channels 24, and between the output face 3 and the surface 8 of the substrate 6. When precursors A, B are supplied from the precursor sources alternatingly and in succession and in pulsed manner from the precursor sources 11, 12 and via the first and second precursor nozzles 21, 23 the surface 8 of the substrate 6 is subjected alternatingly to surface reactions of the first and second precursor A, B in the reaction zones X, Y, Z and thus coating layers are formed on the surface 8 according to the principles of the ALD. This arrangement provides compact reaction zones X, Y, Z in which the pulsed precursor flows of the first and second precursor advance quickly and the pulse frequency may be high. Furthermore the surface 8 of the substrate 6 is alternatingly subjected to both the first and second precursors A, B and the surface 8 of the substrate 6 is coated uniformly in the area of the reaction zones X, Y, Z.

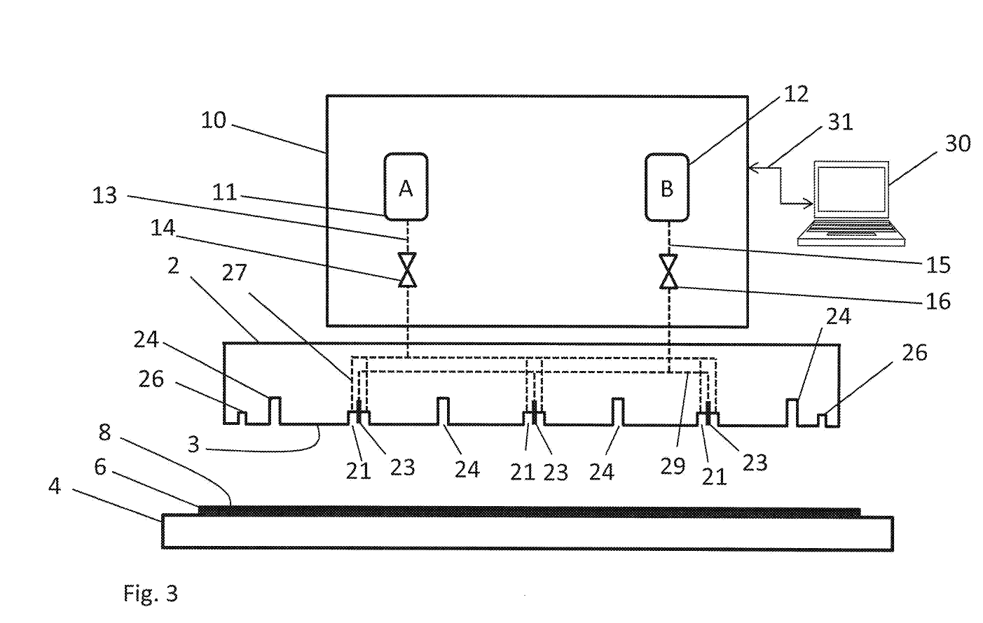

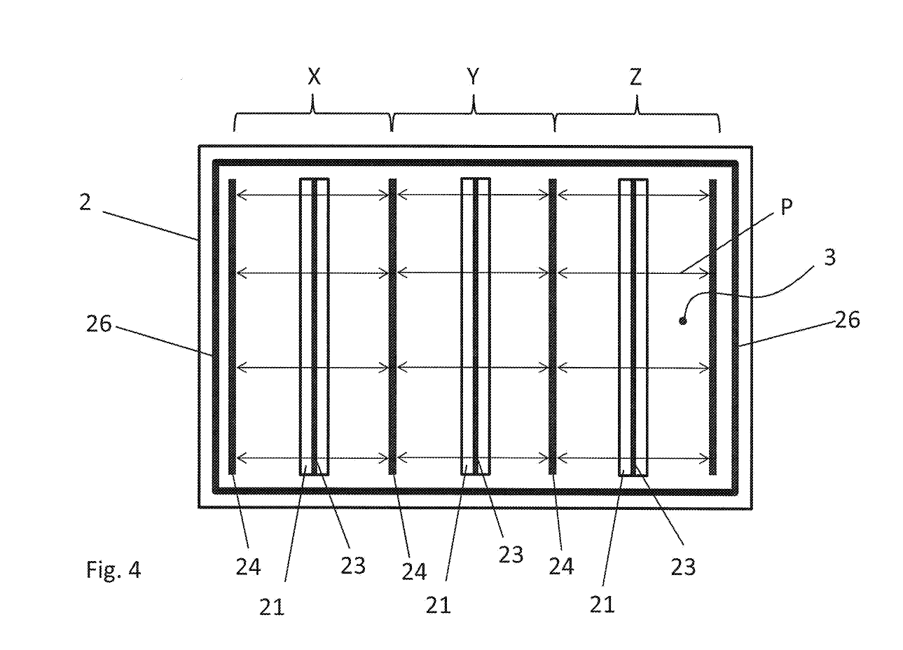

FIGS. 3 and 4 show an alternative embodiment in which the first and second precursor nozzles 21, 23 are provided differently from the embodiment of FIGS. 1 and 2. In this embodiment only the first and second precursor nozzles 21, 23 and branch sub-conduits 27, 29 are altered, all other features are same as in embodiments of FIGS. 1 and 2. In this embodiment the second precursor nozzle 23 is arranged inside the first precursor nozzle 21 such that it divides the first precursor nozzle into two first precursor sub-nozzles, as shown in FIG. 3. The first precursor sub-conduit 13 is branched to each first precursor sub-nozzle 21. Alternatively the first precursor nozzle 21 may be divided with the second precursor nozzle 23 such that the first precursor A may be conveyed to the first precursor nozzle via only one branch precursor conduit 27. According to the above mentioned the second precursor nozzle 23 extends through the first precursor nozzle 21. As shown in FIG. 4, the output face 3 of the nozzle head 2 comprises adjacently in succession in following order: a discharge channel 24, a first precursor nozzle 21 arranged to supply the first precursor A, a second precursor nozzle 23 arranged to supply the second precursor B, a first precursor nozzle 21 arranged to supply the first precursor A and a discharge channel 24. In general, the output face 3 according to the present invention comprises in the following order: a discharge channel 24, one or more first and second precursor channels and a discharge channel 24, repeated one or more times, for forming the reaction zones X, Y, Z between the successive discharge channels 24.

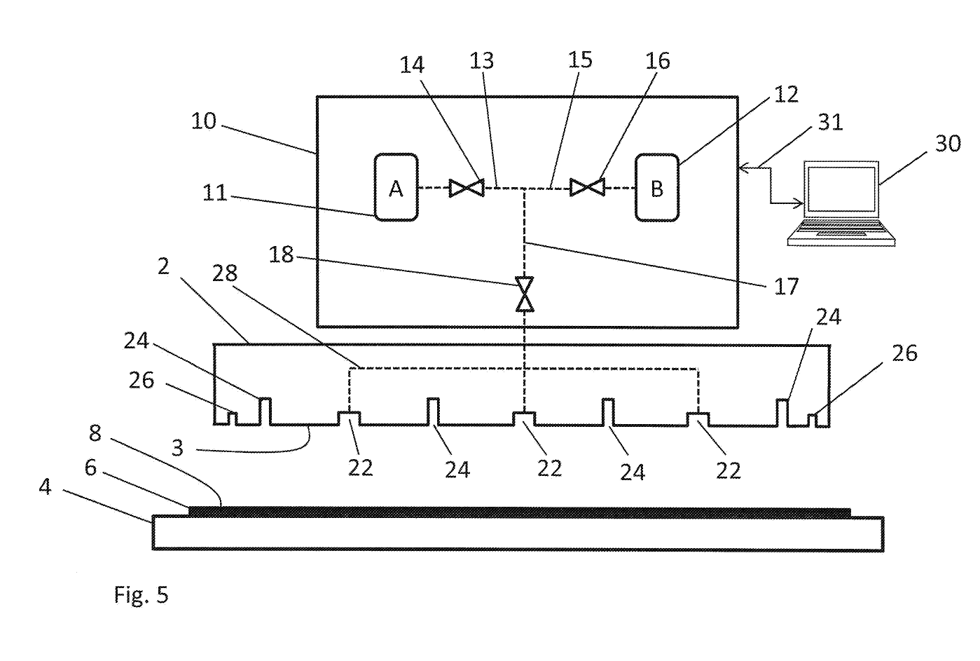

FIG. 5 shows an alternative embodiment of the present invention in which the precursor conduits 13, 15, 17, 28, 27, 29 of the precursor supply system 10 are arranged to convey first precursor A from the first precursor source 11 and second precursor B from the second precursor source 12 to at least one common precursor nozzle 22 provided to the nozzle head 2 for supplying first and second precursor A, B to the surface 8 of the substrate 6 via same common precursor nozzle 22. This means that the same precursor nozzle 22 or nozzles 22 are used for supplying both or all precursors A, B on the surface 8 of the substrate 6. Also possible purge gas may be supplied via the same common precursor nozzle or nozzles 22.

FIG. 5 shows one embodiment in which the precursor supply system 10 comprises a first sub-conduit 13 extending from the first precursor source 11 and a second sub-conduit 15 extending from the second precursor source 12 for conveying the first and second precursor from the precursor sources 11, 12. The first and second sub-conduit 13, 15 are provided with first and second precursor valves 14, 16, respectively, for controlling the flow of the first and second precursor A, B from the first and second precursor sources 11, 12. The precursor supply system 10 further comprises a precursor supply conduit 17, 28 extending to the at least one common precursor nozzle 22. The first sub-conduit 13 is provided between the first precursor source 11 and the precursor supply conduit 17, 28, and the second sub-conduit 15 provided between the second precursor source 12 and the precursor supply conduit 17, 28. Therefore the first and second precursors A, B are conveyed to the common precursor nozzle 22 via the same common precursor supply conduit 17, 28. The precursor supply conduit 17, 28 is provided with a supply valve 18 controlling the precursors A, B supply to the common precursor nozzle 22. The supply valve 18 may also be omitted. The precursor supply conduit 17 is further branched to form branch supply conduits 28 for conveying the precursors A, B to each of the common precursor nozzles 22. Thus nozzle head 2 may comprise two or more common precursor nozzles 22 and precursor supply conduit 17, 28 may branch to two or more branch supply conduits 28 for conveying both the first and second precursor A, B to each common precursor nozzle 22. Alternatively there may be separate sub-conduits 13, 15 and precursor supply conduits 17 for each of the common precursor nozzles 22 from the precursor sources 11, 12. It should be noted that some or part of the precursor conduits 13, 15, 17, 28 may be provided to the nozzle head 2 and some or part of the precursor conduits 13, 15, 17, 28 outside the nozzle head 2. According to the above mentioned at least one of the precursor nozzles 22 is a common precursor nozzle and arranged to supply both the first and second precursor A, B to the surface 8 of the substrate 6. FIG. 5 shows an embodiment in which the nozzle head 2 comprises a precursor conduit 28, or branch conduits 28, extending to the common precursor nozzle 22 and arranged to convey both the first and second precursor A, B to the common precursor nozzle 22. In an alternative embodiment the precursor conduits 13 and 16 may be connected to each other at the nozzle head 2 in the precursor nozzles 22 or at the vicinity of the precursor nozzles 22.

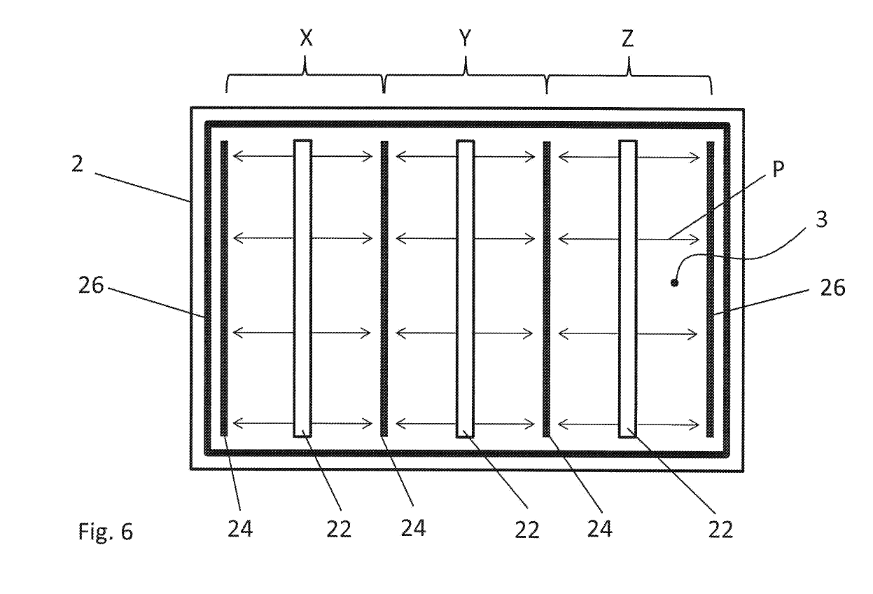

FIG. 6 shows one embodiment of the output face 3 of the nozzle head 2. The output face 3 is arranged over or on the surface 8 of the substrate 6 for supplying the precursors A, B on the surface 8 via the common precursor nozzles 22. As shown in FIG. 6 the common precursor nozzles 22 are longitudinal channels open to the output face 3 and the discharge channels 24 are longitudinal channels open to the output face 3. The common precursor nozzles 22 and the discharge channels 24 extend substantially parallel in the output face 3 for providing a reaction zones X, Y, Z between the adjacent common precursor nozzles 22 and the discharge channels 24. In principle the output face 3 may comprise one or two or more longitudinal common precursor nozzles 22 arranged to supply both the first and second precursor A, B and two or three or more longitudinal discharge channels 24 arranged to discharge precursors. The common precursor nozzles 22 and the discharge channels 24 may be arranged alternatingly in substantially parallel to some other pattern to the output face 3 for providing reaction zones X, Y, Z between the adjacent common precursor nozzles 22 and the discharge channels 24.

The precursors A, B are supplied from the common precursor nozzles 22 and the flow towards the adjacent discharge channels 24 as shown in FIG. 2 with arrows P. Then the reaction zones X, Y and Z are formed between the common precursor nozzle 22 and the adjacent discharge channels 24 and between the output face 3 and the surface 8 of the substrate 6. When precursors A, B are supplied from the precursor sources alternatingly and in succession and in pulsed manner from the precursor sources 11, 12 and via the common precursor nozzles 22 the surface 8 of the substrate 6 is subjected alternatingly to surface reactions of the first and second precursor A, B in the reaction zones X, Y, Z and thus coating layers are formed on the surface 8 according to the principles of the ALD. This arrangement provides compact reaction zones X, Y, Z in which the pulsed precursor flows of the first and second precursor advance quickly and the pulse frequency may be high. Furthermore the surface 8 of the substrate 6 is alternatingly subjected to both the first and second precursors A, B and the surface 8 of the substrate 6 is coated uniformly in the area of the reaction zones X, Y, Z.

It should be noted that the output face 3 may also comprise two separate discharge channels 24 between the precursor nozzles 22 instead of one. Thus there may be a separate discharge channel 24 for both the precursors supplied from the precursor nozzle 22. Further a purge gas nozzle may be provided between these two separate discharge channels 24.

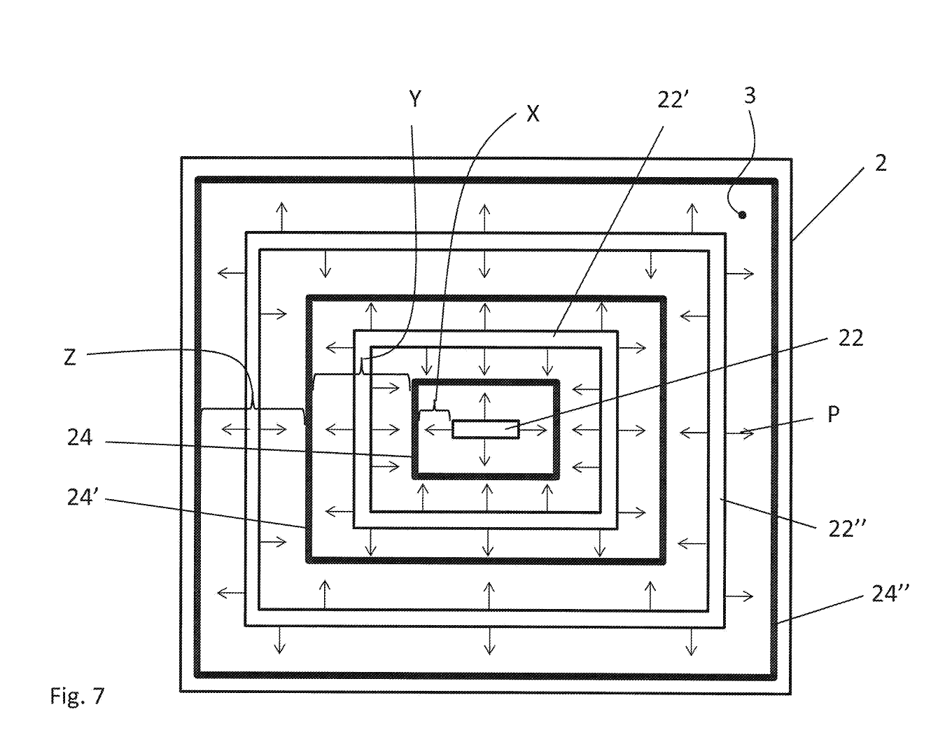

FIG. 7 shows an alternative embodiment of the output face 3 of the nozzle head 2. In this embodiment one of the common precursor nozzles 22 is a nozzle open to the output face 3. The output face 3 further comprises a circumferential channel 24 open to the output face 3 and surrounding the central common precursor nozzle 22. Alternatively the output face could also comprise at least one central discharge channel open to the output face 3 of the nozzle head 2 and at least one of the common precursor nozzles 22 provided as circumferential channel open to the output face 3 and surrounding the central discharge channel 24. Thus the output face 3 may comprise only one central common precursor nozzle or discharge channel and respectively a circumferential discharge channel or common precursor nozzle surrounding it. The circumferential discharge channel enables forming the reaction space without side walls and the circumferential discharge channel closes the reaction space on the sides.

At least one of the common precursor nozzles 22, 22′, 22″ may be a circumferential channel open to the output face 3 and at least one of the discharge channel 24, 24′, 24″ may be a longitudinal channel open to the output face 3 of the nozzle head 2, as shown in FIG. 7. Therefore, the output face 3 may comprise one or more circumferential common precursor nozzles 22′, 22″ arranged to supply both the first and second precursor A, B and one or more circumferential discharge channels 24, 24′, 24″ arranged to discharge precursors. The circumferential common precursor nozzles 22′, 22″ and the circumferential discharge channels 24, 24′, 24″ are arranged to the output face 3 alternately and surrounding each other for providing reaction zones X, Y, Z between the adjacent common precursor nozzles 22, 22′, 22″ and the discharge channel 24, 24′, 24″. Accordingly, the circumferential common precursor nozzles 22 and the circumferential discharge channels 24 are arranged to the output face 3 alternately and surrounding each other such that each common precursor nozzle 22′, 22″ is between two discharge channels 24, 24′, 24″ for providing a reaction zone X, Y, Z between the adjacent common precursor nozzles 22′, 22″ and the discharge channels 24, 24′, 24″. In the embodiment of FIG. 7 there is one central common precursor channel 22 and two, or more, circumferential common precursor channels 22′, 22″. The reaction zones X, Y, Z are formed in the similar manner as described in connection with FIG. 6 and the precursors A, B from in direction of arrows P from the common precursor nozzles 22, 22′, 22″ to the discharge channels 24, 24′, 24″.

According to the above mentioned and the preferable embodiment of the present invention the output face 3 of the nozzle head 2 comprises adjacently in succession in following order: a discharge channel 24, a common precursor nozzle 22 arranged to supply both the first and second precursor A, B and a discharge channel 24 for forming a reaction zone X, Y, Z in which the surface 8 of the substrate 6 is subjected to successive surface reactions of the first and second precursor A, B. The output face 3 of the nozzle head 2 may also comprise the following in succession in following order adjacently: a discharge channel 24, a common precursor nozzle 22 arranged to supply both the first and second precursor A, B and a discharge channel 24, and repeated one or more times for forming two or more reaction zones X, Y, Z, the two or more reaction zones having a shared discharge channel 24.

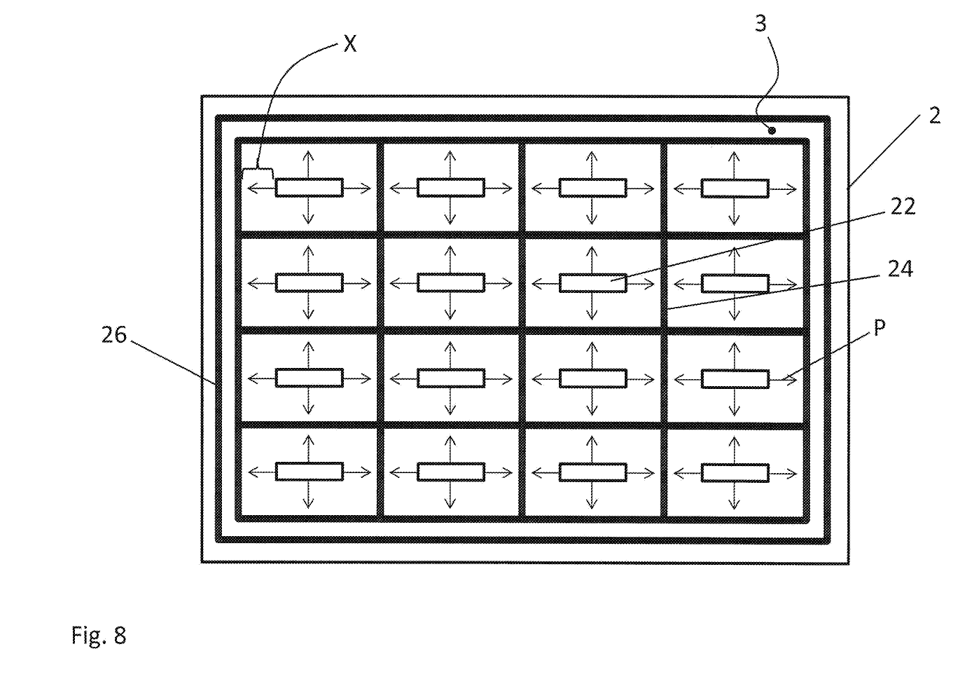

FIG. 8 shows a modification of the nozzle head 2 of FIG. 7. In this embodiment the output face 3 comprises several central common precursor nozzles 22 open to the output face 3 and each of the central common precursor nozzles 22 is surrounded by a circumferential discharge channel 24 open to the output face 3. Thus the output face 3 comprises matrix of central common precursor nozzles 22 surrounded by circumferential discharge channels 24. The precursors flow in the direction of arrows P from the precursor nozzles 22 to the discharge channels 24. Therefore, each pair of central precursor nozzle 22 and the circumferential discharge nozzle 24 surrounding the central precursor nozzle 22 provides a nozzle block and forms a reaction zone X. The output face 3 may thus be provided with one or more adjacent nozzle blocks for forming one or more adjacent reaction zones X or a matrix of nozzle blocks or reaction zones, as shown in FIG. 8. In an alternative embodiment the output face 3 could also comprise one or more central discharge channel open to the output face 3 of the nozzle head 2 and at least one of the common precursor nozzles 22 provided as circumferential channel open to the output face 3 and surrounding the central discharge channel 24. In an alternative embodiment there may be provided a shield gas or purge gas channel between two discharge channels 24 of the adjacent reaction zones X. Thus the purge gas channel separates adjacent reaction zones X from each other and enables coating the surface of the substrate in patterned manner such that adjacent reaction zones X may have different coatings or some reaction zones may be left without coating.

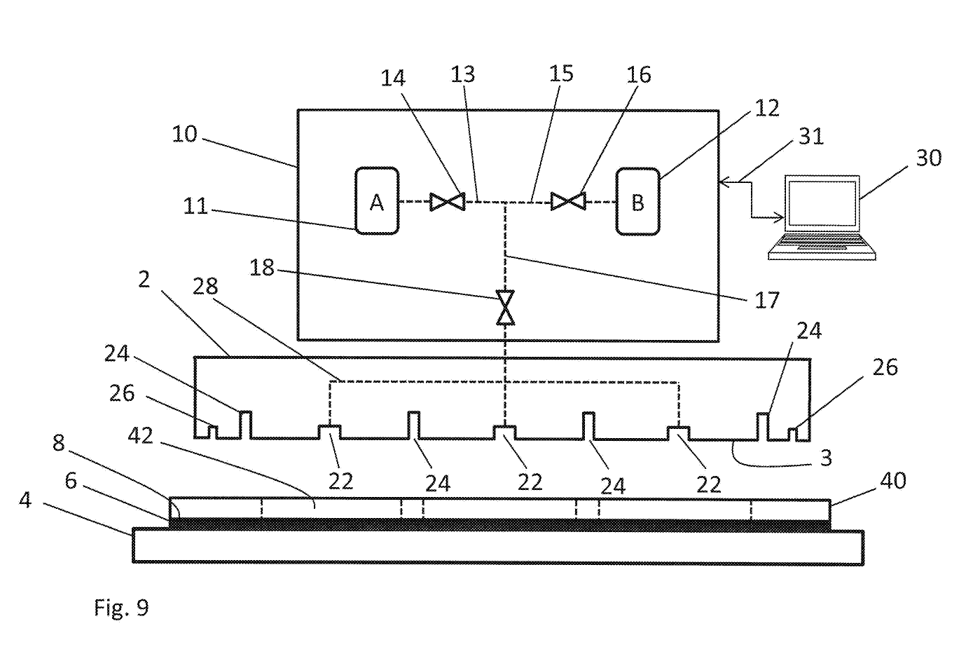

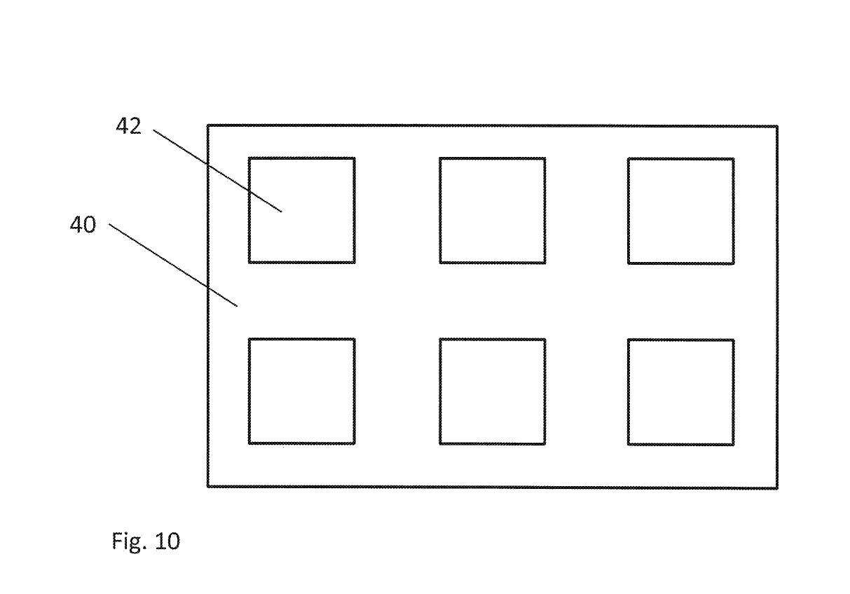

FIG. 9 shows the apparatus of FIG. 5 and a mask 40 arranged between the surface 8 of the substrate 6 and the output face 3 of the nozzle head 2. The mask 40 covers the surface 8 of the substrate and prevents the surface 8 from subjecting to precursors A, B. The mask 40 comprises openings 42 for providing precursor access to the surface 8 of the substrate 6. Thus the precursors A, B may flow through openings 42 and subject the areas of the surface 8 substrate 6 under the openings 42 to the surface reactions of at least the first and second precursors A, B. FIG. 10 shows one embodiment of a mask 40 in which rectangular opening s 42 and provided for forming similar rectangular coated areas on the surface 8 of the substrate. Using a mask 40 only part of the surface of the substrate may be processed. The mask 40 may be manufactured from any suitable material, such as a thin metal plate, paper or plastic. The mask 40 may also be a uniform element without openings for covering part of the surface 8 of the substrate 6 in which coating is not wanted.

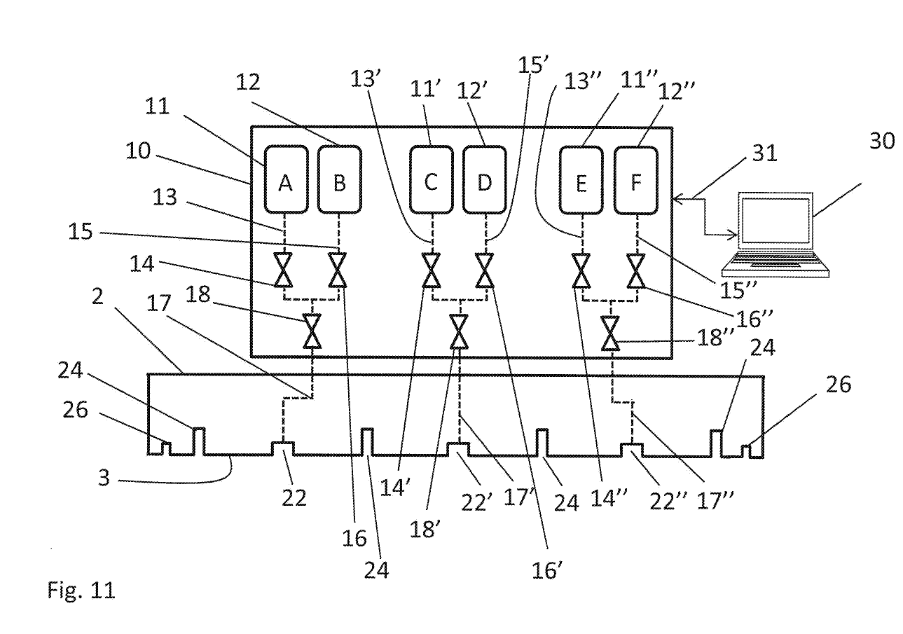

FIG. 11 shows schematically another embodiment of the apparatus of the present invention. The same reference numerals denote same features as in FIGS. 5 to 9 and their description of thus omitted. The apparatus of FIG. 11 comprises three common precursor nozzles 22 which are all arranged to supply two or more precursors to the surface 8 of the substrate 6. The precursor supply system 10 comprises a first precursor source 11 and a second precursor source 12 for the first and second precursors A, B respectively. The precursor supply system 10 further comprises a first sub-conduit 13 extending from the first precursor source 11 and a second sub-conduit 15 extending from the second precursor source 12 for conveying the first and second precursor from the precursor sources 11, 12. The first and second sub-conduits 13, 15 are provided with first and second precursor valves 14, 16, respectively, for controlling the flow of the first and second precursor A, B from the first and second precursor sources 11, 12. The precursor supply system 10 further comprises a precursor supply conduit 17 extending to first common precursor nozzle 22. The first sub-conduit 13 is provided between the first precursor source 11 and the precursor supply conduit 17 and the second sub-conduit 15 provided between the second precursor source 12 and the precursor supply conduit 17. Therefore the first and second precursors A, B are conveyed to the first common precursor nozzle 22 via the same common precursor supply conduit 17. The precursor supply conduit 17 is provided with a supply valve 18 controlling the precursors A, B supply to the first common precursor nozzle 22. The supply valve 18 may also be omitted. The precursor supply system 10 further comprises a third precursor source 11′ and fourth precursor source 12′ for the third precursor C and fourth precursor D, respectively. There are also provided a third sub-conduit 13′ and a fourth sub-conduit 15′ extending from the third precursor source 12′. The third and fourth sub-conduits 13′, 15′ are provided with third and fourth precursor valves 14′, 16′, respectively, and a second precursor supply conduit 17′ extending to second common precursor nozzle 22′, as in connection of the first common precursor nozzle 22. The precursor supply system 10 further also comprises a fifth precursor source 11″ and sixth precursor source 12″ for the fifth precursor E and sixth precursor F, respectively. There are also provided a fifth sub-conduit 13″ and a sixth sub-conduit 15″ extending from the fifth precursor source 12″. The fifth and sixth sub-conduits 13″, 15″ are provided with fifth and sixth precursor valves 14″, 16″, respectively, and a third precursor supply conduit 17″ extending to a third common precursor nozzle 22″, as in connection of the first common precursor nozzle 22. In the embodiment of FIG. 7 there are three common precursor nozzles 22, 22′, 22″ which all area arranged to supply two, or more, precursors A, B, C, D, E, F alternatingly in succession to the surface 8 of the substrate 6. Thus the apparatus and nozzle head 2 provide three reaction zones which each provide different coating on the substrate 6. Thus the substrate 6 may have different coatings on different parts of the surface 8. Alternatively the substrate 6 may be moved in relation to the nozzle head 2 such that the same area of the surface 8 is located under another reaction zone after being processed with in one or more reaction zones for forming different superposed coating layers on the surface 8 of the substrate 6.

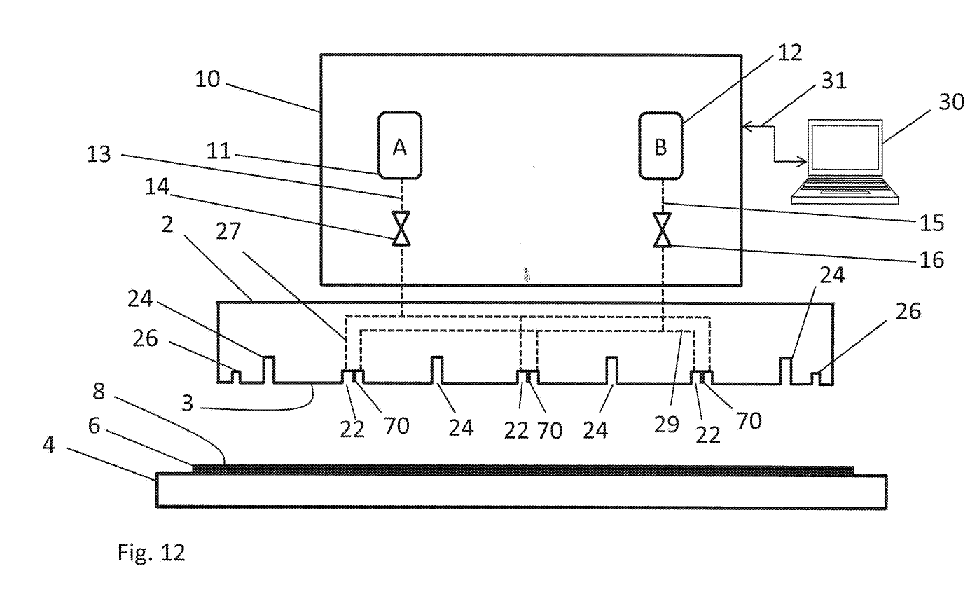

FIG. 12 shows yet an alternative embodiment of the apparatus of the present invention. In this embodiment precursor supply system 10 comprises a first precursor sub-conduit 13 extending from the first precursor source 11 to the common precursor nozzle 22 and arranged to convey first precursor A to the common precursor nozzle 22, and a second precursor sub-conduit 15 extending from the second precursor source 12 to the common precursor nozzle 22 and arranged to convey second precursor B to the common precursor nozzle 22. The precursor conduit sub-conduits 13, 15 may further be branched to two or more branch sub-conduits 27, 29 extending two or more common precursor nozzles 22, as shown in FIG. 12. In this embodiment the first and second precursor A, B are conveyed via separate sub-conduits 13, 27, 15, 29 from the precursor sources 11, 12 to the common nozzle head 22 such that they may be supplied to the surface 8 of the substrate 6 via the same common precursor nozzle 22.

FIG. 12 shows an embodiment in which the apparatus further comprises a plasma generator or plasma electrode 70 provided in connection with the first or second precursor source 11, 12. In FIG. 8 the plasma generator is provided to the common precursor nozzle 22, but alternatively it may be provided to one or more of the precursor conduits 13, 15, 27, 29. The control system 30 may control the use of the plasma generator 70 such that it is turned on only when one of the precursors A or B is supplied to the surface 8 of the substrate 6. The apparatus and nozzle head 2 of the present invention is ideal for using plasma as precursor since plasma radicals remain in the active plasma state only a relatively short time and in the present invention the same precursor flow is conveyed only along a part of the surface 8 of the substrate 6. This means that precursor flow in each reaction zones X, Y, Z is short both in terms of time and distance, and the plasma may remain in an active plasma state along the entire reaction zone X, Y, Z. Clearly arranging active plasma to a conventional batch process in which the precursors are forced to flow through the whole reaction chamber is more involved. Plasma gas may be used as purge gas when plasma is not generator is not used. Plasma gas typically is oxygen containing gas, such as CO or CO₂, or mixtures thereof. The plasma generator 70 comprises a plasma electrode and electronic unit usually external to the apparatus. In this case the plasma gas forms one precursor when plasma is generated with the plasma generator 70. Accordingly one of the precursors may be generated as plasma remotely and supplied as plasma via a precursor nozzle 22. Alternatively one of the precursors may be generated with direct plasma ignited over the substrate or at the precursor nozzle at the proximity of the surface of the substrate.

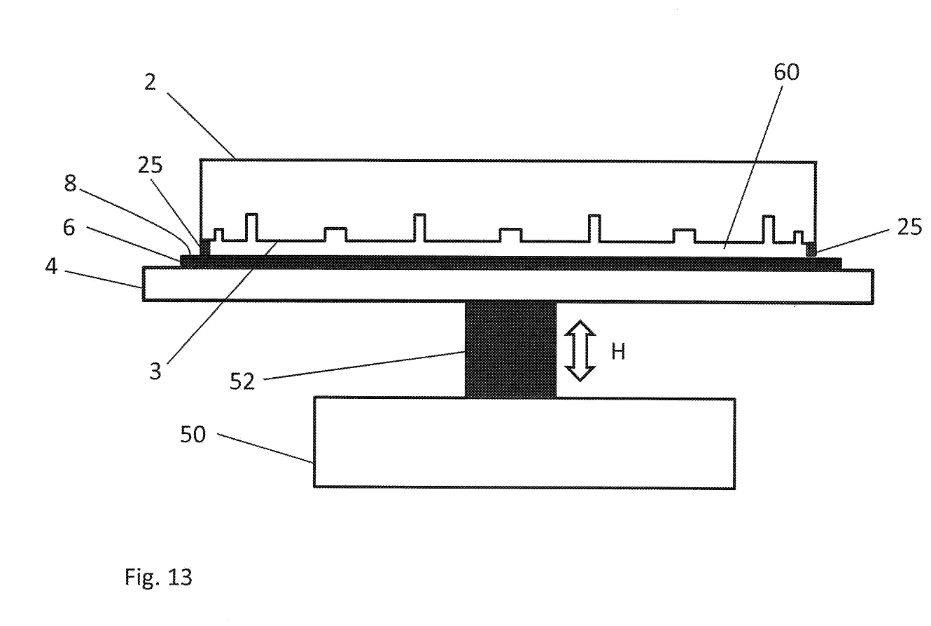

FIG. 13 shows the apparatus in closed operating state in which the nozzle head 2 is arranged over or on the surface 8 of the substrate 6. The apparatus comprises a reaction chamber having a bottom and lid for defining a reaction space 60 in which the surface 8 of the substrate 6 is subjected to surface reactions of at least the first and second precursor A, B. As shown in FIG. 13, in the closed state the nozzle head 2 and the surface 8 of the substrate 6 or the substrate support 4 form the reaction chamber having a reaction space 60. Accordingly the nozzle head 2 may form the lid of the reaction chamber such that the output face 3 is arranged towards the surface 8 of the substrate 6, or the nozzle head 2 may form the bottom of the reaction chamber such that the output face 3 is arranged towards the surface 8 of the substrate 6. The substrate support 4 may be arranged to support the substrate 6 in the reaction chamber such that the substrate support 4 forms the bottom of the reaction chamber. Alternatively substrate support 4 may be arranged to support the substrate 6 in the reaction chamber such that the substrate support 4 forms the lid of the reaction chamber. The nozzle head 2 and output face 3 thereof may be provided with seals 25 on edge or vicinity thereof for sealing the reaction space 60 when the nozzle head 2 is placed on the surface of the substrate 6. The seals may also define the height of the reaction space 60. In the FIG. 9 the nozzle head 2 is placed against the surface 8 of the substrate 6 in the closed state, but alternatively the nozzle head may be placed against the substrate support 4 or bottom or lid of the reaction chamber. This provides a compact structure and prevents material growth on the edge regions of the substrate which may be provided for example with electrical contacts.

FIG. 13 shows also schematically one embodiment of the apparatus of the present invention in which the apparatus comprises an operating unit 50, 52 for arranging the substrate 6 or the surface 8 of the substrate over/under or on the nozzle head 2 or the output face 3 of the nozzle head 2. The operating unit may comprise moving means 52 for moving the nozzle head 2 and/or, substrate 6 and/or substrate support 4 in relation to each other for arranging the nozzle head over or on the surface 8 of the substrate 6. The moving means 52 may comprise any conventional means, such as hydraulic elements, for moving the nozzle head 2 and/or, substrate 6 and/or substrate support 4 in relation to each other. The operating unit may further comprise drive means 50 for operating the moving means 52. The drive means 50 may comprise motors, valves, or electrical connections or the like. The operating unit may be arranged to move the nozzle head 2, or the lid and bottom of the reaction chamber in relation to each other for opening and closing the reaction chamber. The operating unit may also be arranged to move the substrate support 4 or the substrate 6 and the nozzle head 2 in relation to each other for opening and closing the reaction chamber.

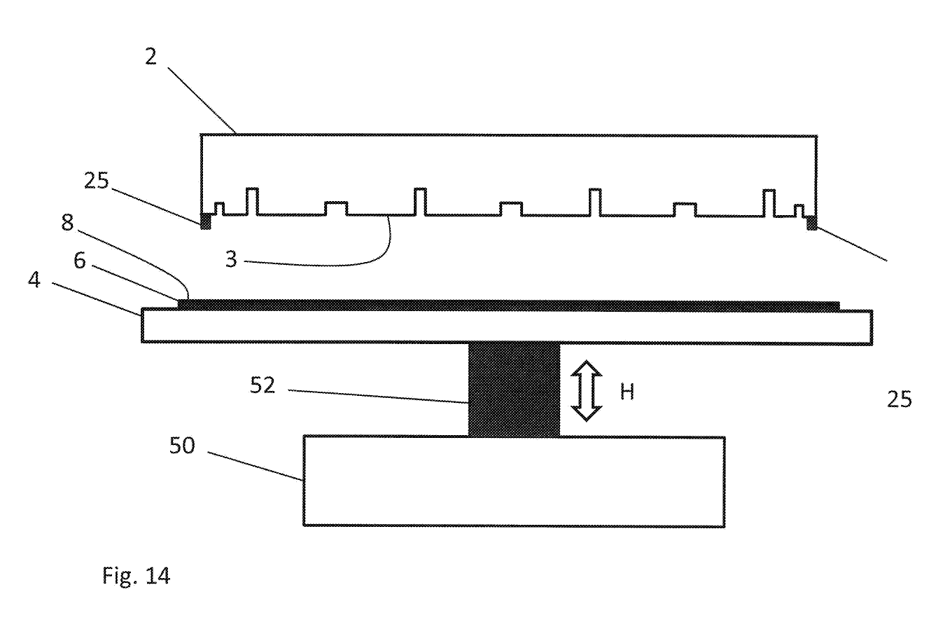

FIG. 14 shows the apparatus and reaction chamber in an open state in which the nozzle head 2 is at a distance from the substrate support 4 and the surface 8 of the substrate 6, and thus the substrate 6 may be loaded into or unloaded from the apparatus. In the embodiment of FIGS. 13, 14 and 15 the operating unit is arranged to lift and lower the substrate 6 vertically as shown by arrow H. It should be noted that the operating unit may also be arranged to move the nozzle head 2 or the substrate 6, substrate support 4, lid or bottom of the reaction chamber in horizontal direction or in a direction between the vertical and the horizontal direction.

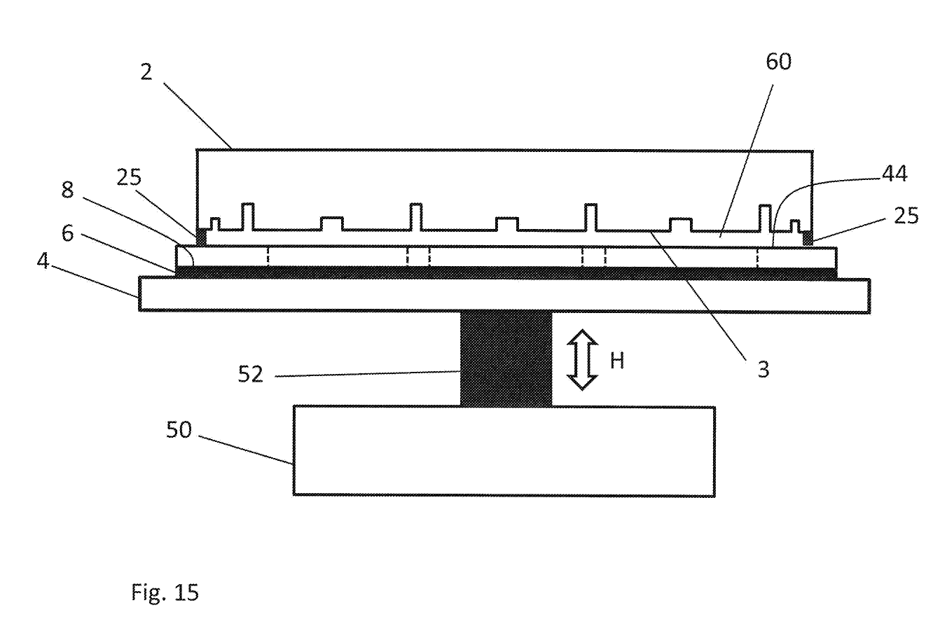

FIG. 15 further shows an embodiment in which mask 40 is used between output face 3 of the nozzle head 2 and the surface 8 of the substrate 6. In this embodiment the nozzle head 2 arranged against the mask 40 and the reaction space 60 formed between the output face 3 and the mask 40 and the surface 8 of the substrate 6 in the areas of the opening 42 of the mask 40.

The present invention provides a method for coating a substrate 6. The method comprises arranging a nozzle head 2 over or on the surface 8 of the substrate 6. The nozzle head comprising at least one precursor nozzle 22, 21, 24 for supplying first and second precursor A, B to the surface 8 of the substrate 6 and at least two discharge channel 24, 26 for discharging precursor A, B from the surface 8 of the substrate 6. The method also comprises subjecting the surface 8 of the substrate 6 to successive surface reactions of at least a first precursor A and a second precursor B. The method further comprises supplying the first and second precursors A, B from the at least one precursor nozzle 22; 21, 23 alternatingly to the surface 8 of the substrate 6 via the output face 3 comprising in the following order: a discharge channel 24, at least one at least one precursor nozzle 22; 21, 23 arranged to supply the first precursor A and the second precursor B and a discharge channel 24. In one embodiment the method comprises supplying alternatingly in succession the first precursor A from a first precursor nozzle 21 via the output face 3 to the surface 8 of the substrate 6 and the second precursor B from a second precursor nozzle 23 via the output face 3 to the surface 8 of the substrate 6 for growing coating layers on the surface 8 of the substrate 6 In an alternative embodiment the method comprises supplying alternatingly in succession the first precursor A and the second precursor B from a common precursor nozzle 22 via the output face 3 to the surface 8 of the substrate 6 for growing coating layers on the surface 8 of the substrate 6.

In the method the surface 8 of the substrate 6 is subjected to successive surface reactions of the at least first precursor A and second precursor B by supplying both the first and second precursors A, B to the surface 8 of the substrate 6 from the precursor nozzles 22, 21, 23 alternatingly in succession for growing coating layers on the surface 8 of the substrate 6. The nozzle head 2 and apparatus of the present invention may be used for carrying out the method. In the method the precursors A, B are supplied alternatingly in succession to the surface 8 of the substrate 6 for forming reaction zones X, Y, Z between the two successive discharge channels 24 in which reaction zone X, Y, Z the surface 8 of the substrate 6 is subjected to surface reaction of the precursors A, B.

It will be obvious to a person skilled in the art that, as the technology advances, the inventive concept can be implemented in various ways. The invention and its embodiments are not limited to the examples described above but may vary within the scope of the claims.

1. A nozzle head for subjecting a surface of a substrate to successive surface reactions of at least a first precursor and a second precursor, the nozzle head having an output face comprising:
one or more precursor nozzles arranged to supply the first precursor and the second precursor to the surface of the substrate; and
at least two discharge channels for discharging precursor from the surface of the substrate,
the output face comprises in the following order:
a discharge channel, at least one precursor nozzle arranged to supply the first precursor and the second precursor and a discharge channel, and wherein
the output face of the nozzle head comprises adjacently in succession in following order: a discharge channel, at least one precursor nozzle arranged to supply the first and second precursor and a discharge channel, and repeated one or more times for forming two or more reaction zones.

2. A nozzle head according to claim 1, wherein the output face comprises in the following order:
a discharge channel, a first precursor nozzle arranged to supply the first precursor, a second precursor nozzle arranged to supply the second precursor and a discharge channel; or
a discharge channel, a first precursor nozzle arranged to supply the first precursor, a second precursor nozzle arranged to supply the second precursor, a first precursor nozzle arranged to supply the first precursor and a discharge channel; or
a discharge channel, a common precursor nozzle arranged to supply both the first and second precursor and a discharge channel.

3. A nozzle head according to claim 1, wherein the nozzle head comprises:
a first precursor conduit extending to the first precursor nozzle and arranged to convey first precursor to the first precursor nozzle, and a second precursor conduit extending to the second precursor nozzle and arranged to convey second precursor to the second precursor nozzle; or
a precursor conduit extending to the common precursor nozzle and arranged to convey both the first and second precursor to the precursor nozzle; or
a first precursor conduit extending to the common precursor nozzle and arranged to convey first precursor to the common precursor nozzle, and a second precursor conduit extending to the common precursor nozzle and arranged to convey second precursor to the common precursor nozzle.

4. A nozzle head according to claim 1 wherein:
the precursor nozzle is a longitudinal channel open to the output face of the nozzle head; or
the precursor nozzle is a longitudinal channel open to the output face of the nozzle head and the discharge channel is a longitudinal channel open to the output face of the nozzle head; or
the precursor nozzle is a longitudinal channel open to the output face of the nozzle head and the discharge channel is a longitudinal channel open to the output face of the nozzle head, the precursor nozzle and the discharge channel extending substantially parallel in the output face of the nozzle head for providing a reaction zone between two the successive discharge channels.

5. A nozzle head according to claim 3, wherein:
the precursor nozzle is a central nozzle open to the output face of the nozzle head; or
the precursor nozzle is a central nozzle open to the output face of the nozzle head and the discharge channel is circumferential channel open to the output face and surrounding the central common precursor nozzle; or
at least one or the discharge channels is a central channel open to the output face of the nozzle head; or
at least one of the discharge channels is a central channel open to the output face of the nozzle head and at least one of the common precursor nozzles is circumferential channel open to the output face and surrounding the central discharge channel.

6. A nozzle head according to claim 3 or 5, wherein:
the precursor nozzle is circumferential channel open to the output face; or
the precursor nozzles is circumferential channel open to the output face and at least one of the discharge channel is a longitudinal channel open to the output face of the nozzle head; or
the precursor nozzle is circumferential channel open to the output face and the discharge channel is a circumferential channel open to the output face of the nozzle head, the circumferential precursor nozzle being arranged to surround the circumferential discharge channel; or
the precursor nozzles is circumferential channel open to the output face and at least one of the discharge channel is a circumferential channel open to the output face of the nozzle head, the circumferential discharge channel being arranged to surround the circumferential precursor nozzle.

7. A nozzle head according to claim 5, wherein:
the output face comprises one or more circumferential common precursor nozzles and one or more circumferential discharge channels, the circumferential common precursor nozzles and the circumferential discharge channels being arranged to the output face alternately and surrounding each other for providing a reaction zone between the adjacent common precursor nozzle and the discharge channel or between successive discharge channels; or
the output face comprises one or more circumferential common precursor nozzles and two or more circumferential discharge channels, the circumferential common precursor nozzles and the circumferential discharge channels being arranged to the output face alternately and surrounding each other such that each common precursor nozzle is between two discharge channels for providing a reaction zone between successive discharge channels; or
the output face comprises one or more circumferential first and second precursor nozzles and one or more circumferential discharge channels, the circumferential first and second precursor nozzles and the circumferential discharge channels being arranged to the output face alternately and surrounding each other for providing a reaction zone between the adjacent first and second precursor nozzles and the discharge channel or between successive discharge channels; or
the output face comprises one or more circumferential first and second precursor nozzles and two or more circumferential discharge channels, the circumferential first and second precursor nozzles and the circumferential discharge channels being arranged to the output face alternately and surrounding each other such that each pair of first and second precursor nozzles is between two discharge channels for providing a reaction zone between successive discharge channels.

8. A nozzle head according to claim 1 wherein the precursor nozzle or the precursor conduit comprises plasma generator or plasma electrode.

9. An apparatus for subjecting a surface of a substrate to successive surface reactions of at least a first precursor and a second precursor, the apparatus comprising:
a nozzle head for supplying precursors to the surface of the substrate, the nozzle head comprises an output face having one or more precursor nozzles arranged to supply the first precursor and the second precursor to the surface of the substrate and at least one discharge channel for discharging precursors from the surface of the substrate; and
a precursor supply system comprising a first precursor source for the first precursor, a second precursor source for the second precursor and precursor conduits for conveying precursor from the first and second precursor sources to the at least one precursor nozzle of the nozzle head,
the output face of the nozzle head comprises in the following order:
a discharge channel, at least one at least one precursor nozzle and a discharge channel, and
the precursor conduits of the precursor supply system are arranged to convey first precursor from the first precursor source and second precursor from the second precursor source to the at least one precursor nozzle provided to the nozzle head for supplying the first and second precursor the surface of the substrate between two successive discharge channels at the output face for forming one or more reaction zones,
wherein the output face of the nozzle head comprises adjacently in succession in following order: a discharge channel, at least one precursor nozzle, arranged to supply the first and second precursor and a dis-charge channel, and repeated one or more times for forming two or more reaction zones.

10. An apparatus according to claim 9, wherein the output face of the nozzle head comprises in the following order:
a discharge channel, a first precursor nozzle arranged to supply the first precursor, a second precursor nozzle arranged to supply the second precursor and a discharge channel; or
a discharge channel a first precursor nozzle arranged to supply the first precursor, a second precursor nozzle arranged to supply the second precursor, a first precursor nozzle arranged to supply the first precursor and a discharge channel; or
a discharge channel, a common precursor nozzle arranged to supply both the first and second precursor and a discharge channel.

11. An apparatus according to claim 9, wherein:
the precursor conduits of the precursor supply system are arranged to convey first precursor from the first precursor source and second precursor from the second precursor source to at least one common precursor nozzle provided to the nozzle head for supplying first and second precursor to the surface of the substrate via same common precursor nozzle; or
the precursor conduits of the precursor supply system are arranged to convey first precursor from the first precursor source to the first precursor nozzle and second precursor from the second precursor source to the second precursor nozzle supplying first and second precursor to the surface of the substrate between successive discharge channels.

12. An apparatus according to claim 11, wherein the precursor supply system comprises:
a precursor supply conduit extending to the at least one common precursor nozzle;
a first sub-conduit provided between the first precursor source and the precursor supply conduit; and
a second sub-conduit provided between the second precursor source and the precursor supply conduit.

13. An apparatus according to claim 12, wherein the nozzle head comprises two or more common precursor nozzles and precursor supply conduit branches to two or more branch supply conduits for conveying both the first and second precursor to each common precursor nozzle.

14. An apparatus according to claim 11, wherein the precursor supply system comprises:
a first sub-conduit provided between the first precursor source and the at least one common precursor nozzle and a second sub-conduit provided between the second precursor source and the at least one common precursor nozzle; or
a first sub-conduit provided between the first precursor source and the at least one first precursor nozzle a second sub-conduit provided between the second precursor source and the at least one second precursor nozzle.

15. An apparatus according to claim 14, wherein:
the nozzle head comprises two or more common precursor nozzles, the first sub-conduit branching to two or more first branch sub-conduits for conveying the first precursor to each common precursor nozzle, and the second sub-conduit branching to two or more second branch sub-conduits for conveying the second precursor to each common precursor nozzle; or
the nozzle head comprises two or more first precursor nozzles, the first sub-conduit branching to two or more first branch sub-conduits for conveying the first precursor to each first precursor nozzle and two or more second precursor nozzles, the second sub-conduit branching to two or more second branch sub-conduits for conveying the second precursor to each second precursor nozzle.

16. An apparatus according to claim 9 wherein the nozzle head is formed as a nozzle head according to claim 9.

17. An apparatus according to claim 9 wherein the apparatus comprises a reaction chamber having a bottom and top for defining a reaction space in which the surface of the substrate is subjected to surface reactions of at least the first and second precursor.

18. An apparatus according to claim 17, wherein:
the nozzle head forms the top of the reaction chamber such that the output face is arranged towards the surface of the substrate; or
the nozzle head forms the bottom of the reaction chamber such that the output face is arranged towards the surface.

19. An apparatus according to claim 17, wherein:
the apparatus comprises a substrate support supporting the substrate in the reaction chamber; or
the apparatus comprises a substrate support supporting the substrate in the reaction chamber, the substrate support forming the bottom of the reaction chamber; or
the apparatus comprises a substrate support supporting the substrate in the reaction chamber, the substrate support forming the lid of the reaction chamber.

20. An apparatus according to claim 17 wherein the apparatus further comprises an operating unit for arranging the nozzle head over the surface of the substrate.

21. An apparatus according to claim 20, wherein the operating unit is arranged to:
move the nozzle head; or
move the top and bottom of the reaction chamber in relation to each other for opening and closing the reaction chamber; or
move the substrate support.

22. An apparatus according to claim 9 wherein the apparatus further comprises a control system arranged to control the supply of the at least first and second precursor alternatingly in succession to the common precursor nozzle or to the first and second precursor nozzles.

23. An apparatus according to claim 9 wherein the apparatus further comprises a mask having openings, the mask being arranged on the output face for subjecting the areas of the surface substrate under the openings to the surface reactions of at least the first and second precursors.

24. An apparatus according to claim 9 wherein the apparatus further comprises a plasma generator or plasma electrode provided in connection with the first or second precursor source, or one or more of the precursor conduits, or the common precursor nozzle.

25. A method for coating a substrate, the method comprises:
arranging a nozzle head over the surface of the substrate, the nozzle head having an output face comprising at least one precursor nozzle for supplying first and second precursor to the surface of the substrate and at least one discharge channel for discharging precursor from the surface of the substrate;
subjecting the surface to successive surface reactions of at least a first precursor and a second precursor;
supplying the first and second precursors from the at least one precursor nozzle to the surface of the substrate via the output face; and
discharging the first and second precursors with discharge channels from the surface of the substrate via the output face,
supplying the first and second precursors from the precursor nozzles alternatingly to the surface of the substrate via the output face, the output face comprising in the following order: discharge channel, at least one precursor nozzle arranged to supply the first precursor and the second precursor and discharge channel, and repeated one or more times for forming two or more reaction zones; and
discharging the first and second precursors with the discharge channels from to the surface of the substrate via the output face, the output face comprising in the following order: discharge channel, at least one precursor nozzle arranged to supply the first precursor and the second precursor and discharge channel, and repeated one or more times for forming two or more reaction zones.

26. A method according to claim 25, wherein
supplying alternatingly in succession the first precursor from a first precursor nozzle via the output face to the surface of the substrate and the second precursor from a second precursor nozzle via the output face to the surface of the substrate for growing coating layers on the surface of the substrate; or
supplying alternatingly in succession the first precursor and the second precursor from a common precursor nozzle via the output face to the surface of the substrate for growing coating layers on the surface of the substrate.

27. A method according to claim 25, wherein arranging a mask having openings between surface of the substrate and the output face of the nozzle head for subjecting the areas of the surface substrate under the openings to the surface reactions of at least the first and second precursors.

28. A method according to claim 25 wherein arranging the nozzle head on the surface of the substrate by moving the nozzle head and the substrate in relation to each other.

29. A method according to claim 25 wherein:
arranging the nozzle head against the surface of the substrate; or
arranging the nozzle head against the mask; or
supporting the substrate to a substrate support and arranging the nozzle head against the substrate support.
